(19) United States
(12) Patent Application Publication
(10) Pub. No.: US 2025/0112445 A1
(43) Pub. Date: Apr. 3, 2025

(54) SEMICONDUCTOR OPTICAL DEVICE

(71) Applicant: Sumitomo Electric Industries, Ltd., Osaka (JP)

(72) Inventors: Naoki FUJIWARA, Osaka-shi (JP); Takashi KATO, Osaka-shi (JP); Kenshi TAKADA, Osaka-shi (JP); Takeshi AOKI, Osaka-shi (JP); Susumu YOSHIMOTO, Osaka-shi (JP); Yuki ITO, Osaka-shi (JP)

(73) Assignee: Sumitomo Electric Industries, Ltd., Osaka (JP)

(21) Appl. No.: 18/789,793

(22) Filed: Jul. 31, 2024

(30) Foreign Application Priority Data
Sep. 29, 2023 (JP) 2023-169026

(51) Int. Cl. H01S 5/34; H01S 5/343

(52) U.S. Cl. CPC H01S 5/3416; H01S 5/3403; H01S 5/3434

(57) ABSTRACT

A semiconductor optical device includes a first n-type III-V group compound semiconductor layer, an active layer, a tunnel junction structure including a p-type III-V group compound semiconductor layer and a second n-type III-V group compound semiconductor layer, and a third n-type III-V group compound semiconductor layer. The first n-type III-V group compound semiconductor layer, the active layer, the p-type III-V group compound semiconductor layer, the second n-type III-V group compound semiconductor layer, and the third n-type III-V group compound semiconductor layer are stacked in this order. The second n-type III-V group compound semiconductor layer has an n-type dopant concentration higher than an n-type dopant concentration of the third n-type III-V group compound semiconductor layer. The p-type III-V group compound semiconductor layer has a strain.

### CROSS REFERENCE TO RELATED APPLICATIONS

This application claims priority based on Japanese Patent Application No. 2023-169026 filed on Sep. 29, 2023, and the entire contents of the Japanese patent application are incorporated herein by reference.

### TECHNICAL FIELD

The present disclosure relates to a semiconductor optical device.

### BACKGROUND

Non-Patent Literature 1 (K. Nakahara et al., “40-Gb/s Direct Modulation With High Extinction Ratio Operation of 1.3-μm InGaAlAs Multiquantum Well Ridge Waveguide Distributed Feedback Lasers”, in IEEE Photonics Technology Letters, vol. 19, no. 19, pp. 1436-1438 Oct. 1, 2007, DOI: 10.1109/LPT. 2007.903530.) discloses a semiconductor laser. The semiconductor laser includes an n-type indium phosphide (InP) substrate, a quantum well layer above the n-type InP substrate, and a p-type indium aluminum arsenide (InAlAs) layer on the quantum well layer.

### SUMMARY

A semiconductor optical device according to an aspect of the present disclosure includes a first n-type III-V group compound semiconductor layer, an active layer, a tunnel junction structure including a p-type III-V group compound semiconductor layer and a second n-type III-V group compound semiconductor layer, and a third n-type III-V group compound semiconductor layer. The first n-type III-V group compound semiconductor layer, the active layer, the p-type III-V group compound semiconductor layer, the second n-type III-V group compound semiconductor layer, and the third n-type III-V group compound semiconductor layer are stacked in this order. The second n-type III-V group compound semiconductor layer has an n-type dopant concentration higher than an n-type dopant concentration of the third n-type III-V group compound semiconductor layer. The p-type III-V group compound semiconductor layer has a strain.

### BRIEF DESCRIPTION OF THE DRAWINGS

FIG. 1 is a cross-sectional view schematically showing a semiconductor optical device according to an embodiment.

FIG. 2 is a plan view schematically showing a semiconductor optical device according to another embodiment.

FIG. 3 is a cross-sectional view taken along line III-III in FIG. 2.

FIG. 4 is a cross-sectional view showing a step in a method of manufacturing the semiconductor optical device in FIG. 2.

FIG. 5 is a cross-sectional view schematically showing a semiconductor optical device according to still another embodiment.

FIG. 6 is a cross-sectional view showing a step in a method of manufacturing the semiconductor optical device in FIG. 5.

FIG. 7 is a graph showing an example of the relationship between an energy and a density of states.

FIG. 8 is a graph showing an example of an energy band diagram when a strain is −2%.

FIG. 9 is a graph showing an example of an energy band diagram when a strain is −1%.

FIG. 10 is a graph showing an example of an energy band diagram when a strain is −0.5%.

FIG. 11 is a graph showing an example of an energy band diagram when a strain is 0%.

FIG. 12 is a graph showing an example of an energy band diagram when a strain is 0.5%.

FIG. 13 is a graph showing an example of an energy band diagram when a strain is 1%.

FIG. 14 is a graph showing an example of an energy band diagram when a strain is 2%.

### DETAILED DESCRIPTION

In the semiconductor laser described in Non-Patent Literature 1, optical loss may occur due to the p-type InAlAs layer.

The present disclosure provides a semiconductor optical device allowing a reduced optical loss due to the p-type semiconductor layer.

### Description of Embodiments of Present Disclosure

First, embodiments of the present disclosure will be listed and described.

(1) A semiconductor optical device includes a first n-type III-V group compound semiconductor layer, an active layer, a tunnel junction structure including a p-type III-V group compound semiconductor layer and a second n-type III-V group compound semiconductor layer, and a third n-type III-V group compound semiconductor layer. The first n-type III-V group compound semiconductor layer, the active layer, the p-type III-V group compound semiconductor layer, the second n-type III-V group compound semiconductor layer, and the third n-type III-V group compound semiconductor layer are stacked in this order. The second n-type III-V group compound semiconductor layer has an n-type dopant concentration higher than an n-type dopant concentration of the third n-type III-V group compound semiconductor layer. The p-type III-V group compound semiconductor layer has a strain.

In general, in the p-type III-V group compound semiconductor layer, light absorption occurs due to intervalence band absorption. According to the semiconductor optical device, the thickness of the p-type III-V group compound semiconductor layer can be reduced, and thus the optical loss due to the p-type III-V group compound semiconductor layer can be reduced. The p-type III-V group compound semiconductor layer included in the tunnel junction structure has a relatively high p-type dopant concentration. When the p-type dopant concentration is high, the light absorption due to intervalence band absorption is also increased. Even in such a case, since the p-type III-V group compound semiconductor layer has a strain, the optical loss due to the p-type III-V group compound semiconductor layer can be reduced.

(2) In the above (1), the p-type III-V group compound semiconductor layer may be a first p-type III-V group compound semiconductor layer. The semiconductor optical device may further include a second p-type III-V group compound semiconductor layer disposed between the first p-type III-V group compound semiconductor layer and the active layer.

(3) In the above (2), the second p-type III-V group compound semiconductor layer may have a first portion and a second portion adjacent to the first portion. The third n-type III-V group compound semiconductor layer may have a third portion and a fourth portion adjacent to the third portion. The tunnel junction structure may be not disposed between the second portion and the fourth portion but may be disposed between the first portion and the third portion.

(4) In any one of the above (1) to (3), the strain may be a tensile strain.

(5) In any one of (1) to (4), an absolute value of the strain may be 0.5% or more.

(6) In any one of (1) to (5), the semiconductor optical device may have a mesa including the third n-type III-V group compound semiconductor layer and the tunnel junction structure.

(7) In any one of the above (1) to (6), the third n-type III-V group compound semiconductor layer may have a thickness larger than a thickness of the tunnel junction structure.

### Details of Embodiments of Present Disclosure

Hereinafter, embodiments of the present disclosure will be described in detail with reference to the accompanying drawings. In the description of the drawings, the same or equivalent elements are denoted by the same reference numerals, and redundant description thereof will be omitted.

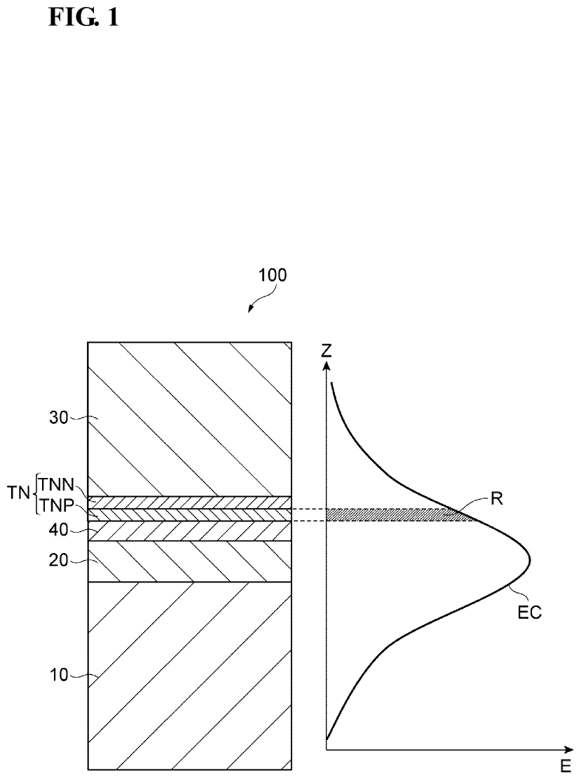

FIG. 1 is a cross-sectional view schematically showing a semiconductor optical device according to an embodiment. A semiconductor optical device 100 shown in FIG. 1 may be a semiconductor laser or a semiconductor optical amplifier (SOA). Semiconductor optical device 100 may be an edge emitting semiconductor laser or a surface emitting semiconductor laser. Semiconductor optical device 100 may be a distributed feedback (DFB) laser, a distributed Bragg reflector (DBR) laser, or a Fabry-Perot (FP) laser. Semiconductor optical device 100 may have an emission wavelength of 1.3 μm to 1.55 μm. Semiconductor optical device 100 may be used for optical communication or may not be used for optical communication.

Semiconductor optical device 100 includes a first n-type III-V group compound semiconductor layer 10, an active layer 20, a tunnel junction structure TN, and a third n-type III-V group compound semiconductor layer 30. Tunnel junction structure TN includes a p-type III-V group compound semiconductor layer TNP and a second n-type III-V group compound semiconductor layer TNN. N-type III-V group compound semiconductor layer 10, active layer 20, p-type III-V group compound semiconductor layer TNP, n-type III-V group compound semiconductor layer TNN, and n-type III-V group compound semiconductor layer 30 are stacked in this order. Semiconductor optical device 100 may further include a second p-type III-V group compound semiconductor layer 40 disposed between p-type III-V group compound semiconductor layer TNP and active layer 20.

N-type III-V group compound semiconductor layer 10 may include indium phosphide (InP). The n-type dopant concentration of n-type III-V group compound semiconductor layer 10 may be from 1×10¹⁷ cm⁻³ to 1×10¹⁹ cm⁻³, and is, for example, 1×10¹⁸ cm⁻³. The thickness of n-type III-V group compound semiconductor layer 10 may be from 0.1 μm to 300 μm, and is, for example, 150 μm. When semiconductor optical device 100 is fabricated by bonding to a silicon on insulator (SOI) substrate, the thickness of n-type III-V group compound semiconductor layer 10 is from 0.1 μm to 5 μm. When semiconductor optical device 100 includes an InP substrate, the thickness of n-type III-V group compound semiconductor layer 10 is from 100 μm to 300 μm. N-type III-V group compound semiconductor layer 10 may be a cladding layer.

Active layer 20 may have a quantum well structure such as a multi quantum well structure. Active layer 20 may include indium gallium arsenide phosphide (InGaAsP). Active layer 20 may be undoped. The thickness of active layer 20 may be smaller than the thickness of n-type III-V group compound semiconductor layer 10. The thickness of active layer 20 may be from 100 nm to 500 nm, and is, for example 250 nm. Active layer 20 may be a core layer.

N-type III-V group compound semiconductor layer TNN may include gallium indium arsenide (GaInAs), indium aluminum arsenide (InAlAs), or a mixed crystal of GaInAs and InAlAs. N-type III-V group compound semiconductor layer TNN have an n-type dopant concentration higher than an n-type dopant concentration of n-type III-V group compound semiconductor layer 30. The n-type dopant concentration of n-type III-V group compound semiconductor layer TNN may be higher than the n-type dopant concentration of n-type III-V group compound semiconductor layer 10. The n-type dopant concentration of n-type III-V group compound semiconductor layer TNN may be from 1×10¹⁸ cm⁻³ to 2×10²⁰ cm⁻³, and is, for example, 3×10¹⁹ cm⁻³. The thickness of n-type III-V group compound semiconductor layer TNN may be smaller than the thickness of active layer 20. The thickness of n-type III-V group compound semiconductor layer TNN may be from 5 nm to 30 nm, and is, for example, 15 nm. N-type III-V group compound semiconductor layer 30 may not have a strain.

P-type III-V group compound semiconductor layer TNP may include GalnAs, InAlAs, or a mixed crystal of GaInAs and InAlAs. An example of the p-type dopant includes carbon. The p-type dopant concentration of p-type III-V group compound semiconductor layer TNP may be from 1×10¹⁸ cm⁻³ to 2×10²⁰ cm⁻³, and is, for example, 1.8×10¹⁸ cm⁻³. The thickness of p-type III-V group compound semiconductor layer TNP may be smaller than the thickness of active layer 20. The thickness of p-type III-V group compound semiconductor layer TNP may be from 5 nm to 30 nm, and is, for example, 15 nm.

P-type III-V group compound semiconductor layer TNP has a strain. The strain is a strain with respect to n-type III-V group compound semiconductor layer 10. The strain may be a tensile strain or a compressive strain. When the strain has a positive value, the strain is a tensile strain. When the strain has a negative value, the strain is compressive strain. The absolute value of the strain may be 0.5% or more, or may be 1% or more. The absolute value of the strain may be 3% or less, or may be 2% or less.

N-type III-V group compound semiconductor layer 30 may include InP. The n-type dopant concentration of n-type III-V group compound semiconductor layer 30 may be from 1×10¹⁷ cm⁻³ to 1×10¹⁹ cm⁻³, and is, for example, 1×10¹⁸ cm⁻³. N-type III-V group compound semiconductor layer 30 may have a thickness larger than a thickness of tunnel junction structure TN. The thickness of tunnel junction structure TN is the sum of the thickness of p-type III-V group compound semiconductor layer TNP and the thickness of n-type III-V group compound semiconductor layer TNN. The thickness of n-type III-V group compound semiconductor layer 30 may be larger than the thickness of active layer 20. The thickness of n-type III-V group compound semiconductor layer 30 may be smaller than the thickness of n-type III-V group compound semiconductor layer 10. The thickness of n-type III-V group compound semiconductor layer 30 may be from 1 μm to 10 μm, and is, for example, 2 μm.

P-type III-V group compound semiconductor layer 40 may include InP. The p-type dopant concentration of p-type III-V group compound semiconductor layer 40 may be smaller than the p-type dopant concentration of p-type III-V group compound semiconductor layer TNP. The p-type dopant concentration of p-type III-V group compound semiconductor layer 40 may be from 1×10¹⁷ cm⁻³ to 1×10¹⁹ cm⁻³, an is, for example, 7×10¹⁷ cm⁻³. P-type III-V group compound semiconductor layer 40 may have a thickness larger than the thickness of tunnel junction structure TN. The thickness of p-type III-V group compound semiconductor layer 40 may be smaller than the thickness of n-type III-V group compound semiconductor layer 30, or may be smaller than the thickness of active layer 20. The thickness of p-type III-V group compound semiconductor layer 40 may be from 50 nm to 500 nm, and is, for example, 200 nm. N-type III-V group compound semiconductor layer 30, tunnel junction structure TN, and p-type III-V group compound semiconductor layer 40 may constitute a cladding layer.

FIG. 1 also shows a graph showing an example of the relationship between a position in a stacking direction of semiconductor optical device 100 and an electric field intensity. A vertical axis Z of the graph represents the position of semiconductor optical device 100 in the stacking direction. A horizontal axis E of the graph represents the intensity of the electric field component of a standing wave of light. A curve EC in the graph represents an electric field intensity distribution at each position. The ratio (optical confinement factor) of the area of a region R corresponding to p-type III-V group compound semiconductor layer TNP to the integral value of the curve EC is about 1%. When a certain layer is used as a part of a waveguide, the increase in the optical loss of the waveguide due to the layer is a value obtained by multiplying the optical loss of the material of the layer by the optical confinement factor. If the optical loss of p-type III-V group compound semiconductor layer TNP as a material is 1000 cm⁻¹, the increase in the optical loss of semiconductor optical device 100 due to p-type III-V group compound semiconductor layer TNP is approximately 10 cm⁻¹. Considering that the optical loss of a waveguide of a typical semiconductor optical device is from 5 cm⁻¹ to 20 cm⁻¹, the increase in optical loss of 10 cm⁻¹ is not a small value. This indicates that the reduction of the optical loss due to p-type III-V group compound semiconductor layer TNP has an effect on the improvement of the characteristics in semiconductor optical device 100. When the optical confinement factor is reduced by reducing the thickness of p-type III-V group compound semiconductor layer TNP, the optical loss of semiconductor optical device 100 can be reduced.

In the p-type III-V group compound semiconductor layer, light absorption typically occurs due to intervalence band absorption. The intervalence band absorption is light absorption due to a transition between sub bands in the valence band (for example, a transition between a split-off band and a heavy hole band). In a semiconductor optical device having a normal PIN structure, a p-type III-V semiconductor layer having a large thickness is provided near an active layer, and thus, an increase in optical loss due to intervalence band absorption is large. Semiconductor optical device 100 of the present embodiment has a tunnel junction structure TN, and can flow a hole current from n-type III-V group compound semiconductor layer 30 toward active layer 20 by using a tunnel effect. Thus, it is not necessary to provide a thick p-type semiconductor layer for allowing a current to flow through the active layer. According to semiconductor optical device 100, p-type III-V group compound semiconductor layer TNP included in tunnel junction structure TN has a relatively high p-type dopant concentration in order to cause a good tunnel effect. When the p-type dopant concentration is high, light absorption due to the intervalence band absorption is also increased. Even in such a case, since p-type III-V group compound semiconductor layer TNP has a strain, the optical loss due to p-type III-V group compound semiconductor layer TNP as a material can be reduced, and an increase in the optical loss of semiconductor optical device 100 due to p-type III-V group compound semiconductor layer TNP can be avoided. As a result, the threshold current of semiconductor optical device 100 can be reduced, and the efficiency of conversion from electricity to light can be improved. It is estimated that the threshold current is reduced by about 10% and the conversion efficiency is improved by about 20% as compared with a PIN structure having a thick p-type III-V group compound semiconductor layer on the active layer.

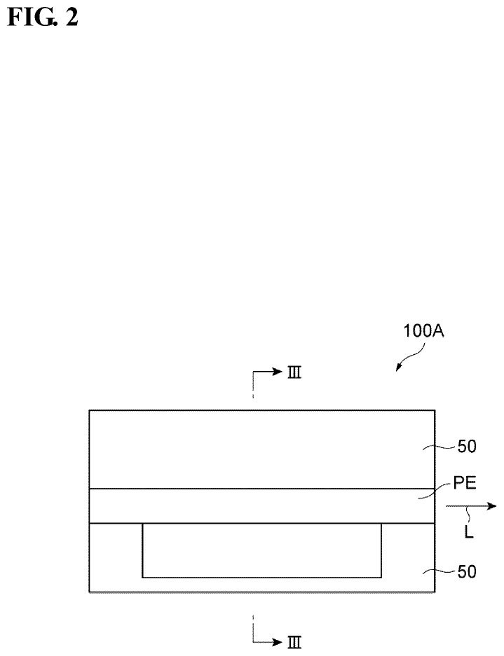

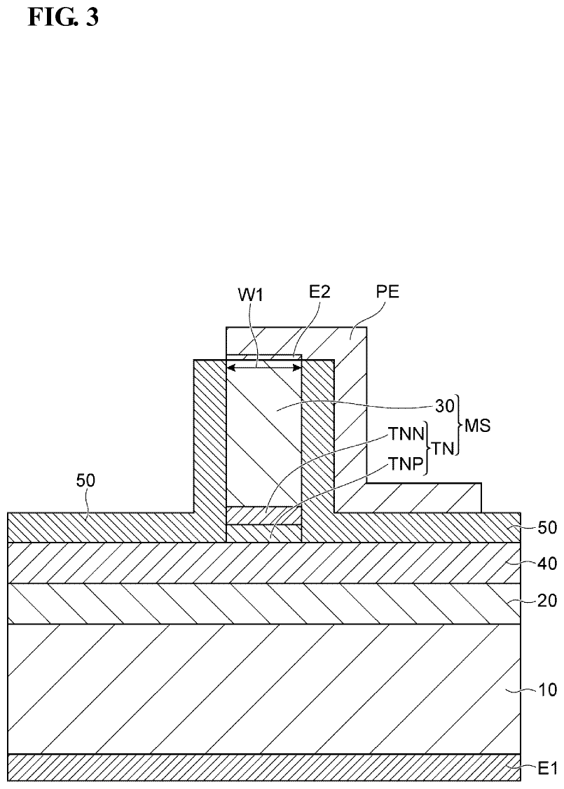

FIG. 2 is a plan view schematically showing a semiconductor optical device according to another embodiment. FIG. 3 is a cross-sectional view taken along line III-III in FIG. 2. A semiconductor optical device 100A shown in FIG. 2 and FIG. 3 is a ridge-type semiconductor laser.

Semiconductor optical device 100A includes n-type III-V group compound semiconductor layer 10, active layer 20, tunnel junction structure TN, and n-type III-V group compound semiconductor layer 30. Semiconductor optical device 100A may further include p-type III-V group compound semiconductor layer 40. Semiconductor optical device 100A may further include an electrode E1 connected to n-type III-V group compound semiconductor layer 10. Electrode E1 may be a ground electrode. Semiconductor optical device 100A may include a mesa MS including n-type III-V group compound semiconductor layer 30 and tunnel junction structure TN. Mesa MS may have a width W1 at the top surface of mesa MS. Width W1 may be from 1.5 μm to 2 μm. Semiconductor optical device 100A may further include an insulating layer 50 covering the side wall of mesa MS. Insulating layer 50 is provided on p-type III-V group compound semiconductor layer 40. Insulating layer 50 may have an opening at the top surface of mesa MS. An electrode E2 may be provided at the opening and connected to n-type III-V group compound semiconductor layer 30. Electrode E2 may be in ohmic contact with n-type III-V group compound semiconductor layer 30. A pad electrode PE may be connected to electrode E2. Pad electrode PE is provided on insulating layer 50. When a voltage is applied between electrode E1 and electrode E2, laser light L is emitted from an end surface of semiconductor optical device 100 in an extending direction of mesa MS. Semiconductor optical device 100A also achieves the same effects as semiconductor optical device 100.

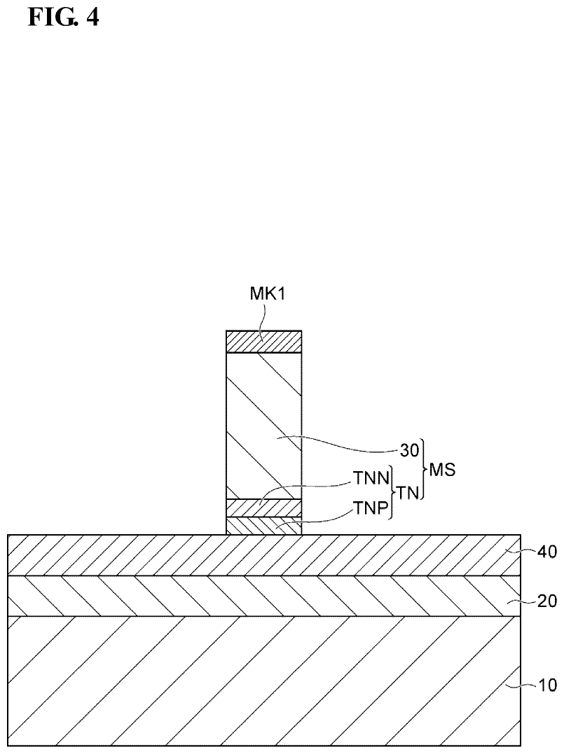

FIG. 4 is a cross-sectional view showing a step in a method of manufacturing the semiconductor optical device in FIG. 2. Semiconductor optical device 100A may be manufactured, for example, as follows. First, n-type III-V group compound semiconductor layer 10, active layer 20, p-type III-V group compound semiconductor layer 40, tunnel junction structure TN, and n-type III-V group compound semiconductor layer 30 are stacked in this order to prepare a stacked body. Next, a mask MK1 is formed on the stacked body. Next, n-type III-V group compound semiconductor layer 30 and tunnel junction structure TN are etched using mask MK1, thereby forming mesa MS (see FIG. 4). N-type III-V group compound semiconductor layer 30 may be dry-etched. Tunnel junction structure TN may be wet-etched. Furthermore, p-type III-V group compound semiconductor layer 40 and active layer 20 may be etched. After the etching, mask MK1 is removed. Next, insulating layer 50 is formed on p-type III-V group compound semiconductor layer 40 and mesa MS, and an opening is formed on the top surface of mesa MS by photolithography and etching. Next, electrode E1 and electrode E2 are formed, and pad electrode PE is formed on electrode E2.

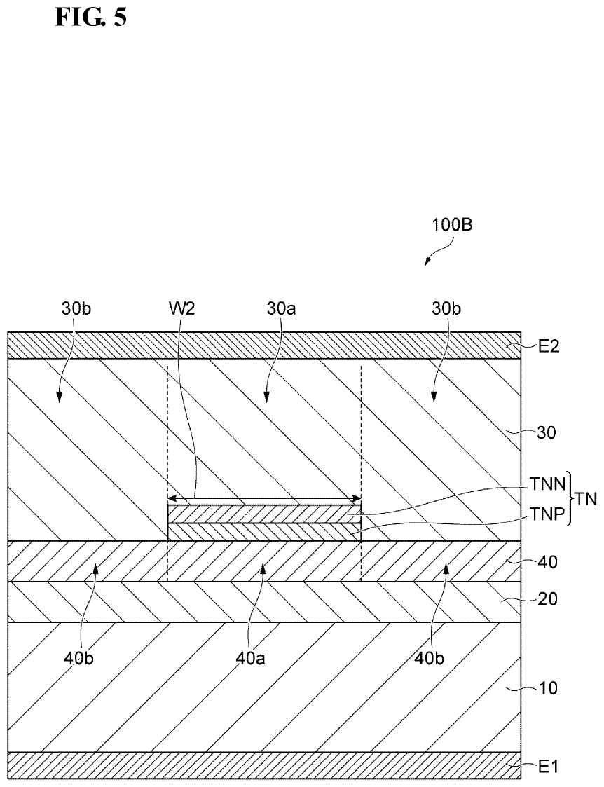

FIG. 5 is a cross-sectional view schematically showing a semiconductor optical device according to still another embodiment. A semiconductor optical device 100B shown in FIG. 5 is a broad contact type semiconductor laser.

Semiconductor optical device 100B includes n-type III-V group compound semiconductor layer 10, active layer 20, tunnel junction structure TN, and n-type III-V group compound semiconductor layer 30. Semiconductor optical device 100B further includes p-type III-V group compound semiconductor layer 40. Semiconductor optical device 100B may further include electrode E1 connected to n-type III-V group compound semiconductor layer 10. Semiconductor optical device 100B may further include electrode E2 connected to n-type III-V group compound semiconductor layer 30.

P-type III-V group compound semiconductor layer 40 has a first portion 40a and a second portion 40b adjacent to first portion 40a. First portion 40a may be disposed between two second portions 40b. N-type III-V group compound semiconductor layer 30 has a third portion 30a and a fourth portion 30b adjacent to third portion 30a. Third portion 30a may be disposed between two fourth portions 30b. Tunnel junction structure TN is not disposed between second portion 40b and fourth portion 30b, but is disposed between first portion 40a and third portion 30a. Thus, the width of n-type III-V group compound semiconductor layer 30 is larger than a width W2 of tunnel junction structure TN. Electrode E2 is in direct contact with third portion 30a and fourth portion 30b. The width of electrode E2 is larger than width W2 of tunnel junction structure TN. The width of p-type III-V group compound semiconductor layer 40 is larger than width W2 of tunnel junction structure TN. Width W2 is, for example, 50 μm.

According to semiconductor optical device 100B, since current is less likely to flow between fourth portion 30b and second portion 40b, leakage current can be reduced. Semiconductor optical device 100B also achieves the same effects as semiconductor optical device 100 and semiconductor optical device 100A.

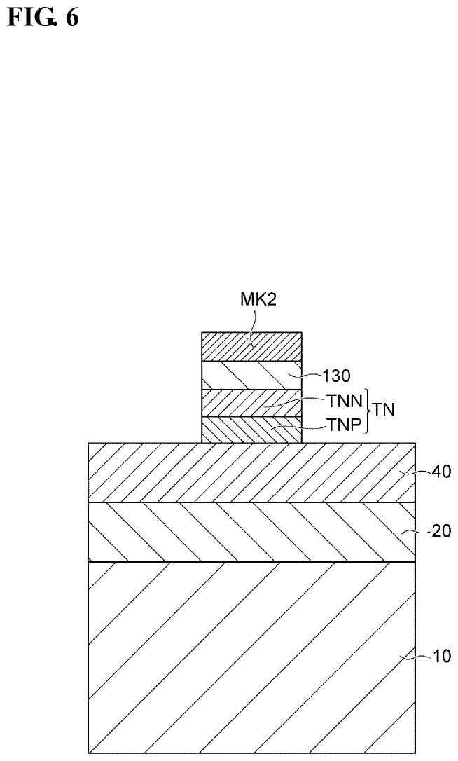

FIG. 6 is a cross-sectional view showing a step in a method of manufacturing the semiconductor optical device in FIG. 5. Semiconductor optical device 100B may be manufactured, for example, as follows. First, n-type III-V group compound semiconductor layer 10, active layer 20, p-type III-V group compound semiconductor layer 40, tunnel junction structure TN, and an n-type III-V group compound semiconductor layer 130 are stacked in this order to prepare a stacked body. N-type III-V group compound semiconductor layer 130 includes the same material as n-type III-V group compound semiconductor layer 30. Next, a mask MK2 is formed on the stacked body. Next, n-type III-V group compound semiconductor layer 130 and tunnel junction structure TN are etched using mask MK2, thereby forming a mesa (see FIG. 6). N-type III-V group compound semiconductor layer 130 may be dry-etched. Tunnel junction structure TN may be wet-etched. By using a selective etchant in the wet etching, p-type III-V group compound semiconductor layer 40 remains without being etched. By leaving p-type III-V group compound semiconductor layer 40, current is prevented from directly flowing from fourth portion 30b to active layer 20 without passing through tunnel junction structure TN. After the etching, mask MK2 is removed. Next, an n-type III-V group compound semiconductor layer is formed on p-type III-V group compound semiconductor layer 40 and the mesa, thereby forming n-type III-V group compound semiconductor layer 30 (see FIG. 5). Next, electrode E1 and electrode E2 are formed.

Various experiments conducted for evaluating the semiconductor optical device will be described below. The experiments described below are not intended to limit the present invention.

### First Experiment

A simulation is performed for the semiconductor optical device having the structure shown in FIG. 1 by a sp3d5s * tight binding method. A gallium composition x is set to 0.172 so that the p-type GaₓIn₁₋ₓAs layer of the tunnel junction structure has a strain of −2% with respect to InP. The photoluminescence wavelength of the active layer is 1550 nm. That is, the energy corresponding to the oscillation wavelength of the semiconductor optical device was 0.80 eV. The p-type dopant concentration of the p-type GaₓIn₁₋ₓAs layer is 2.4×10¹⁹ cm⁻³. A Fermi level Ef is −1.0 eV. The temperature in the simulation is 300K.

### Second Experiment

The second experiment is performed in the same manner as the first experiment except that the strain of the p-type GaₓIn₁₋ₓAs layer of the tunnel junction structure is set to −1%. The gallium composition x is 0.322. The p-type dopant concentration is determined so that the Fermi level Ef is about −1.0 eV.

### Third Experiment

The third experiment is performed in the same manner as the first experiment except that the strain of the p-type GaₓIn₁₋ₓAs layer of the tunnel junction structure is set to −0.5%. The gallium composition x is 0.395. The p-type dopant concentration is determined so that the Fermi level Ef is about −1.0 eV.

### Fourth Experiment

The fourth experiment is performed in the same manner as the first experiment except that the strain of the p-type GaₓIn₁₋ₓAs layer of the tunnel junction structure is set to 0%. The gallium composition x is 0.468. The p-type dopant concentration is determined so that the Fermi level Ef is about −1.0 eV. The p-type dopant concentration is 1×10²⁰ cm⁻³.

### Fifth Experiment

The fifth experiment is performed in the same manner as the first experiment except that the strain of the p-type GaₓIn₁₋ₓAs layer of the tunnel junction structure is set to 0.5%. The gallium composition x is 0.540. The p-type dopant concentration is determined so that the Fermi level Ef is about −1.0 eV.

### Sixth Experiment

The sixth experiment is performed in the same manner as the first experiment except that the strain of the p-type GaₓIn₁₋ₓAs layer of the tunnel junction structure is set to 1%. The gallium composition x is 0.612. The p-type dopant concentration is determined so that the Fermi level Ef is about −1.0 eV.

### Seventh Experiment

The seventh experiment is performed in the same manner as the first experiment except that the strain of the p-type GaₓIn₁₋ₓAs layer of the tunnel junction structure is set to 2.0%. The gallium composition x is 0.752. The p-type dopant concentration was determined so that the Fermi level Ef is about −1.0 eV. The p-type dopant concentration is 1.8×10¹⁹ cm⁻³.

### Density of States of Holes

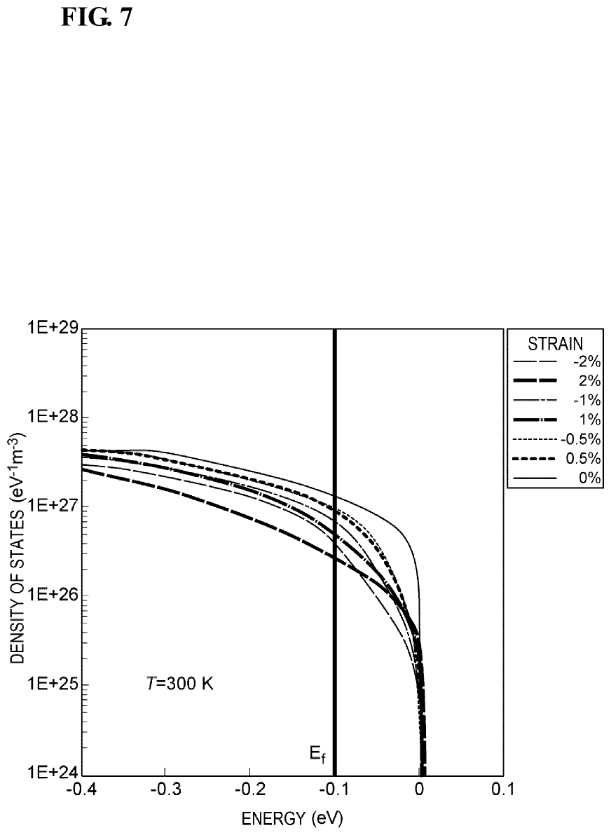

In the first experiment to the seventh experiment, the density of states of holes in the p-type GaₓIn₁₋ₓAs layer is calculated by simulation. The results are shown in FIG. 7. FIG. 7 is a graph showing an example of the relationship between an energy and a density of states. A horizontal axis represents the energy (eV). A vertical axis represents the density of states (eV⁻¹m⁻³) of holes in the p-type GaₓIn₁₋ₓAs layer. As shown in FIG. 7, when the absolute value of the strain is larger than zero, the density of states of holes at the Fermi level Ef becomes smaller than the density of states of holes when the absolute value of the strain is zero. When the density of states of holes is small, the intervalence band absorption is suppressed, and thus, the optical loss due to the p-type GaₓIn₁₋ₓAs layer can be reduced. Furthermore, as shown in FIG. 7, for the same absolute value of the strain, the density of states is smaller when the strain has a positive value (tensile strain) than when the strain has a negative value (compressive strain). Thus, the optical loss due to the p-type GaₓIn₁₋ₓAs layer can be further reduced when the strain is a tensile strain than when the strain is a compressive strain.

### Energy Band Diagram

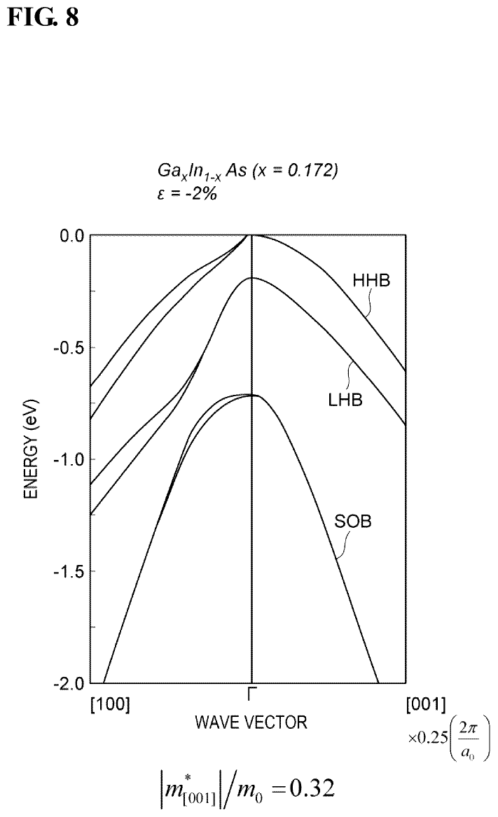

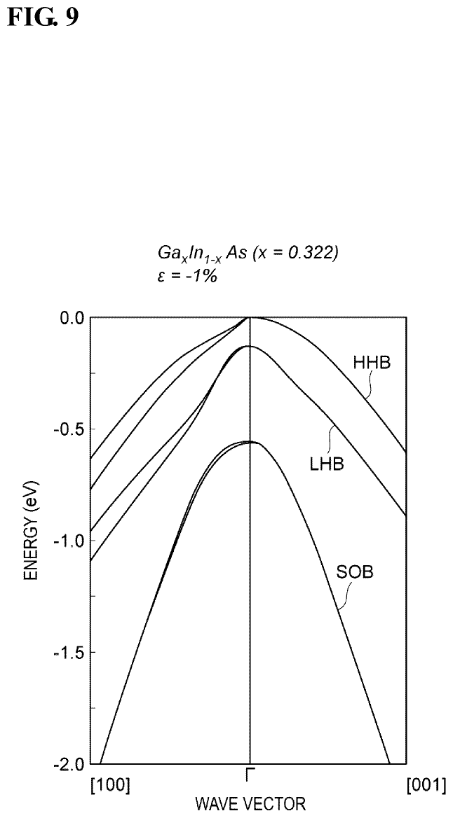

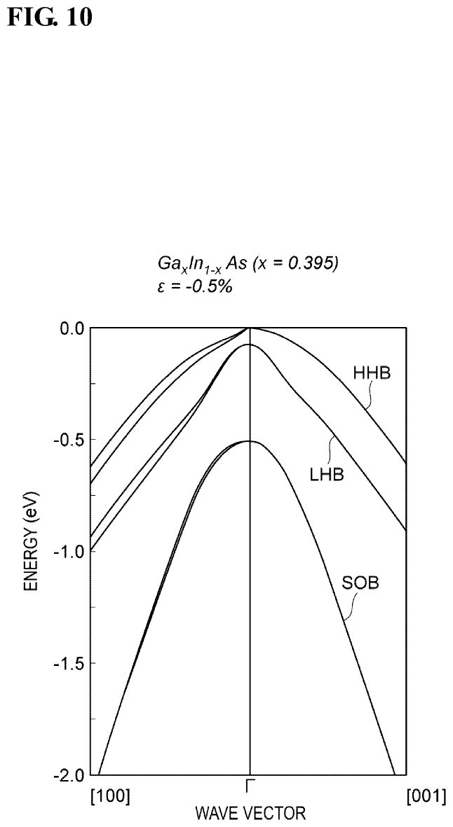

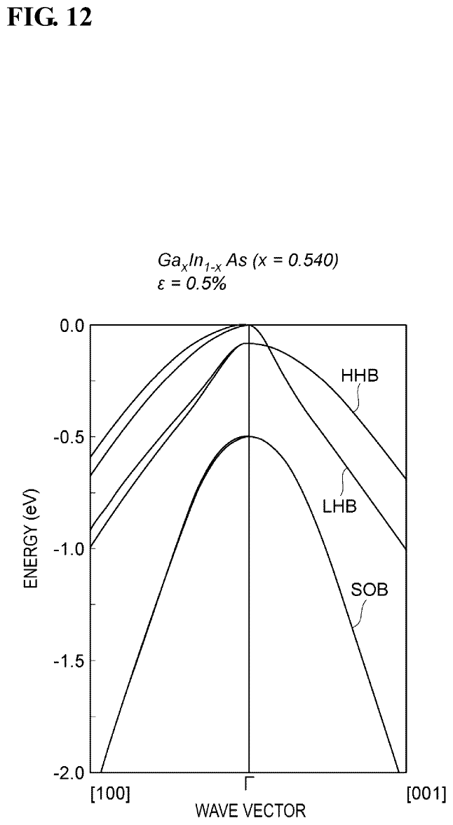

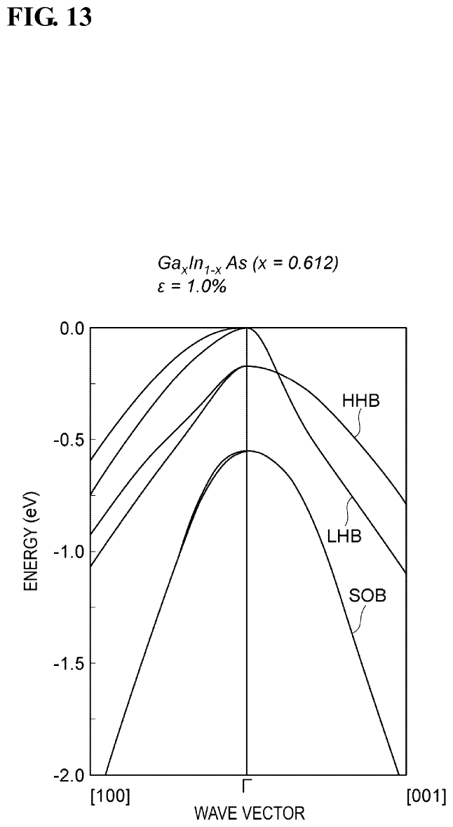

In the first experiment to the seventh experiment, energy band diagrams are created by simulation. The results are shown in FIG. 8 to FIG. 14. FIG. 8 to FIG. 14 are graphs showing examples of energy band diagrams when the strain ε is −2%, −1%, −0.5%, 0%, 0.5%, 1%, and 2%, respectively. A horizontal axis represents a wave vector. A vertical axis represents an energy (eV). In each of the graphs, a heavy hole band HHB, a light hole band LHB, and a split-off band SOB are shown.

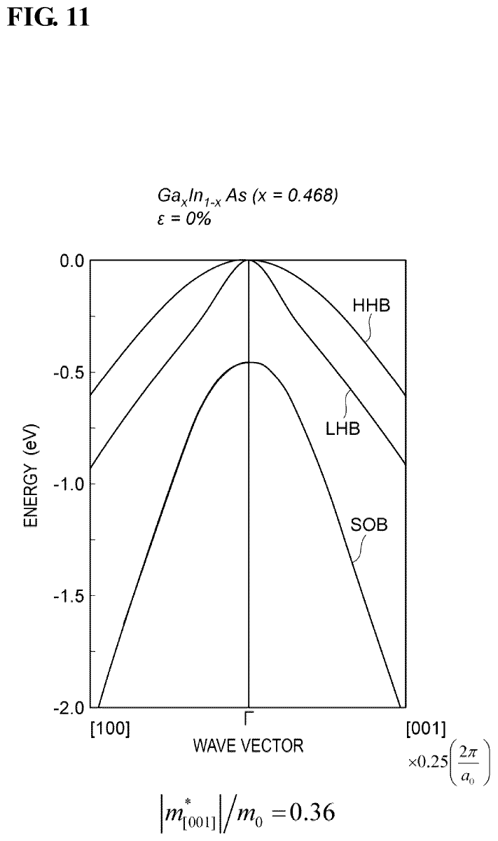

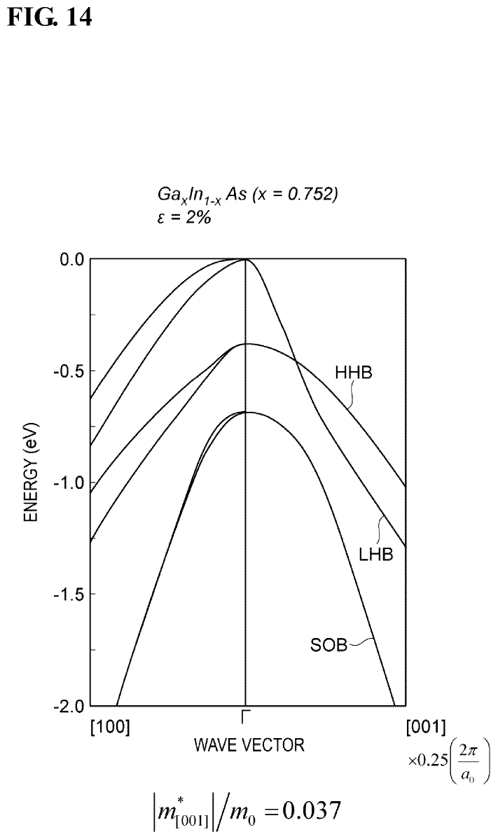

As shown in FIG. 8, when the strain is −2%, the effective mass (|m*_{[011}]|/m₀) of holes is 0.32. In FIG. 8, a₀ represents wavelength. As shown in FIG. 11, when the strain is 0%, the effective mass (|m*_{[011}]|/m₀) of holes is 0.36. In FIG. 11, a₀ represents wavelength. As shown in FIG. 14, when the strain is 2%, the effective mass of holes is 0.037. The holes (holes having a minimum energy) located at the top near the Γ point of each of the graphs mainly contribute to electrical conduction. When the effective mass of holes is small, the conduction of the holes is improved. When the strain has a negative value (compressive strain) or zero, heavy holes contribute mainly to the electrical conduction, as shown in FIG. 8 and FIG. 11. On the other hand, when the strain has a positive value (tensile strain), as shown in FIG. 14, light holes mainly contribute to the electrical conduction. Thus, the conduction of the holes is improved when the strain is a tensile strain.

When the strain is −2%, the band gap wavelength between the valence band and the conduction band is 2340 nm. When the strain is 2%, the band gap wavelength between the valence band and the conduction band is 1495 nm. Since the oscillation wavelength of laser is 1550 nm, when the strain is 2%, light absorption due to the band gap between the valence band and the conduction band is suppressed. Thus, light absorption due to the p-type GaₓIn₁₋ₓAs layer can be suppressed when the strain has a positive value (tensile strain) than when the strain has a negative value (compressive strain).

Although the exemplary embodiments of the present invention have been described in detail, the present invention is not limited to the above-described embodiments.

The embodiments disclosed herein are to be considered as illustrative and non-restrictive in all respects. The scope of the present invention is defined by the appended claims rather than the sense described above, and is intended to include all modifications within the scope and meaning equivalent to the appended claims.

What is claimed is:

1. A semiconductor optical device comprising:
a first n-type III-V group compound semiconductor layer;
an active layer;
a tunnel junction structure including a p-type III-V group compound semiconductor layer and a second n-type III-V group compound semiconductor layer; and
a third n-type III-V group compound semiconductor layer,
wherein the first n-type III-V group compound semiconductor layer, the active layer, the p-type III-V group compound semiconductor layer, the second n-type III-V group compound semiconductor layer, and the third n-type III-V group compound semiconductor layer are stacked in this order,
the second n-type III-V group compound semiconductor layer has an n-type dopant concentration higher than an n-type dopant concentration of the third n-type III-V group compound semiconductor layer, and
the p-type III-V group compound semiconductor layer has a strain.

2. The semiconductor optical device according to claim 1,
wherein the p-type III-V group compound semiconductor layer is a first p-type III-V group compound semiconductor layer, and
the semiconductor optical device further comprises a second p-type III-V group compound semiconductor layer disposed between the first p-type III-V group compound semiconductor layer and the active layer.

3. The semiconductor optical device according to claim 2,
wherein the second p-type III-V group compound semiconductor layer has a first portion and a second portion adjacent to the first portion,
the third n-type III-V group compound semiconductor layer has a third portion and a fourth portion adjacent to the third portion, and
the tunnel junction structure is not disposed between the second portion and the fourth portion but is disposed between the first portion and the third portion.

4. The semiconductor optical device according to claim 1, wherein the strain is a tensile strain.

5. The semiconductor optical device according to claim 1, wherein an absolute value of the strain is 0.5% or more.

6. The semiconductor optical device according to claim 1, further comprising:
a mesa including the third n-type III-V group compound semiconductor layer and the tunnel junction structure.

7. The semiconductor optical device according to claim 1, wherein the third n-type III-V group compound semiconductor layer has a thickness larger than a thickness of the tunnel junction structure.
